(19) United States
(12) Patent Application Publication
(10) Pub. No.: US 2023/0178524 A1
(43) Pub. Date: Jun. 8, 2023

(54) DISPLAY SUBSTRATE, DISPLAY DEVICE, AND MANUFACTURING METHOD FOR DISPLAY SUBSTRATE

(71) Applicant: BOE Technology Group Co., Ltd., Beijing (CN)

(72) Inventors: Qian JIN, Beijing (CN); Wei HUANG, Beijing (CN); Yu TIAN, Beijing (CN); Qian SUN, Beijing (CN)

(21) Appl. No.: 17/921,598

(22) PCT Filed: May 19, 2021
(86) PCT No.: PCT/CN2021/094483

§ 371 Date: Oct. 26, 2022

(30) Foreign Application Priority Data
Jun. 16, 2020 (CN) 202010546970.7

(51) Int. Cl. H01L 25/075; H01L 33/50

(52) U.S. Cl. CPC H01L 25/0753; H01L 33/50; H01L 2933/0091; H01L 2933/0041

(57) ABSTRACT

Provided are a display substrate, a display device, and a manufacturing method for a display substrate. The display substrate includes: a base substrate; a dielectric layer, which is located on one side of the base substrate, the dielectric layer comprising a plurality of recessed portions; a plurality of first-type light-emitting diodes, one of the first-type light-emitting diodes being located in one of the recessed portions; and a photoluminescence structure, the photoluminescence structure being located in at least some of the recessed portions, and being located on the side of the first-type light-emitting diode that faces away from the base substrate.

### CROSS REFERENCE TO RELATED APPLICATIONS

The present disclosure claims priority to Chinese Patent Application No. 202010546970.7, filed to the China Patent Office on Jun. 16, 2020 and entitled “DISPLAY PANEL, DISPLAY DEVICE, AND MANUFACTURING METHOD FOR DISPLAY PANEL”, the entire contents of which are incorporated herein by reference.

### FIELD

The present disclosure relates to the technical field of display, in particular to a display substrate, a display apparatus and a manufacturing method for the display substrate.

### BACKGROUND

Red mini-type LEDs, blue mini-type LEDs and green mini-type LEDs in the related art need to grow on different wafer substrates (including sapphire, GaAs, single-crystal Si, SiC, etc.) during preparation, and will be respectively manufactured. The blue mini-type LEDs and the green mini-type LEDs are relatively mature in industry development, and are relatively good in electroluminescence performance, but the red mini-type LEDs are not mature in industry development, and are low in electroluminescence efficiency. When display devices are manufactured, the mini-type LEDs can achieve active matrix drive only when transferred from the wafer substrates to an array substrate.

### SUMMARY

A display substrate provided by an embodiment of the present disclosure, includes: a base substrate; a dielectric layer, located on one side of the base substrate, and including a plurality of recessed portions; a plurality of first-type light-emitting diodes, one of the first-type light-emitting diodes being located in one of the recessed portions; and a photoluminescence structure, the photoluminescence structure being located in at least some of the recessed portions, located on a side, facing away from the base substrate, of the first-type light-emitting diode, and configured to convert light of a first wave length emitted by the first-type light-emitting diode into light of a second wave length.

In one possible implementation, the display substrate further includes: a plurality of second-type light-emitting diodes located on a side, away from the base substrate, of the dielectric layer, and a height from the second-type light-emitting diode to the base substrate is different from a height from the first-type light-emitting diode to the base substrate.

In one possible implementation, the dielectric layer includes a first sub-dielectric layer and a second sub-dielectric layer, and the second sub-dielectric layer is located on a side, facing away from the base substrate, of the first sub-dielectric layer; and the recessed portions are through holes penetrating through the second sub-dielectric layer, and the second-type light-emitting diodes are located on a side, facing away from the first sub-dielectric layer, of the second sub-dielectric layer, and are parallel to the first-type light-emitting diodes in a direction parallel to the base substrate.

In one possible implementation, the first-type light-emitting diodes and the second-type light-emitting diodes are distributed in a plurality of rows and columns; and in the same row, the first-type light-emitting diodes and the second-type light-emitting diodes are alternately distributed; and in the same column, the first-type light-emitting diodes and the second-type light-emitting diodes are alternately distributed.

In one possible implementation, for the first-type light-emitting diodes in the same row, first-type light-emitting diodes spaced with other one first-type light-emitting diode are provided with a photoluminescence structure.

In one possible implementation, first-type light-emitting diodes not provided with the photoluminescence structure are further provided with a scattering structure located in the recessed portion on a side facing away from the base substrate.

In one possible implementation, light extraction colors of the first-type light-emitting diodes of the recessed portions are the same; and light extraction colors of the second-type light-emitting diodes are the same.

In one possible implementation, the first-type light-emitting diodes are blue light light-emitting diodes, the second-type light-emitting diodes are green light light-emitting diodes, and a material of the photoluminescence structure is a quantum dot material excited by blue light to emit red light.

In one possible implementation, the display substrate further includes: a drive structure located between the base substrate and the first sub-dielectric layer, and the drive structure includes a first-type transistor correspondingly and electrically connected with the first-type light-emitting diodes, and a second-type transistor correspondingly and electrically connected with the second-type light-emitting diodes.

In one possible implementation, in the recessed portions, a first-type connecting pad is further arranged between the first-type light-emitting diodes and the first sub-dielectric layer; and a second-type connecting pad is further arranged between the second sub-dielectric layer and the second-type light-emitting diodes; the first-type connecting pad electrically connects the first-type light-emitting diodes and the first-type transistor by a via hole penetrating through the first sub-dielectric layer; and the second-type connecting pad electrically connects the second-type light-emitting diodes and the second-type transistor by a via hole penetrating through the first sub-dielectric layer and the second sub-dielectric layer.

An embodiment of the present disclosure further provides a display apparatus, including the display substrate provided by embodiments of the present disclosure.

An embodiment of the present disclosure further provides a manufacturing method of the display substrate provided by embodiments of the present disclosure, includes: providing a base substrate; forming a dielectric layer with a plurality of recessed portions on one side of the base substrate; arranging a first-type light-emitting diode in each recessed portion; and forming a photoluminescence structure on a side, facing away from the base substrate, of the first-type light-emitting diodes in at least some of the recessed portions.

In one possible implementation, the forming the dielectric layer with the plurality of recessed portions on one side of the base substrate, includes: forming a first sub-dielectric layer on one side of the base substrate; forming a second sub-dielectric layer on a side, facing away from the base substrate, of the first sub-dielectric layer; and through a patterning process, forming a through hole penetrating through the second sub-dielectric layer on the second sub-dielectric layer to serve as the recessed portion.

In one possible implementation, the arranging the first-type light-emitting diode in each recessed portion, includes: through a fluid self-assembly process, arranging the first-type light-emitting diode in each recessed portion.

In one possible implementation, the forming the photoluminescence structure on the side, facing away from the base substrate, of the first-type light-emitting diodes in at least some of the recessed portions, includes: through an ink-jet printing process or a spin-coating process, forming the photoluminescence structure covering the first-type light-emitting diode in at least some of the recessed portions.

In one possible implementation, after the forming the photoluminescence structure on the side, facing away from the base substrate, of the first-type light-emitting diodes in at least some of the recessed portions, the manufacturing method further includes: arranging a plurality of second-type light-emitting diodes on a side, facing away from the base substrate, of the dielectric layer.

In one possible implementation, the manufacturing method further includes: forming a scattering structure coating the first-type light-emitting diodes in the recessed portion not provided with the photoluminescence structure.

### BRIEF DESCRIPTION OF THE DRAWINGS

FIG. 1 is a section view of a display substrate provided by an embodiment of the present disclosure.

FIG. 2 is a top view of a display substrate provided by an embodiment of the present disclosure.

FIG. 3 is a distribution schematic diagram of first-type light-emitting diodes and second-type light-emitting diodes provided by an embodiment of the present disclosure.

FIG. 4 is a specific section view of a display substrate provided by an embodiment of the present disclosure.

FIG. 5 is a schematic diagram of a manufacturing process of a display substrate provided by an embodiment of the present disclosure.

FIG. 6 is a schematic structural diagram in which a first-type transistor and a second-type transistor are prepared in an embodiment of the present disclosure.

FIG. 7 is a schematic structural diagram in which a second sub-dielectric layer is prepared in an embodiment of the present disclosure.

FIG. 8 is a schematic structural diagram in which recessed portions are prepared in an embodiment of the present disclosure.

FIG. 9 is a schematic structural diagram in which a first connecting pad and a second connecting pad are prepared in an embodiment of the present disclosure.

FIG. 10 is a schematic structural diagram in which first-type light-emitting diodes are prepared in an embodiment of the present disclosure.

FIG. 11 is a schematic structural diagram in which second-type light-emitting diodes are prepared in an embodiment of the present disclosure.

FIG. 12 is a schematic structural diagram in which a scattering structure is prepared in an embodiment of the present disclosure.

FIG. 13 is a schematic structural diagram in which a packaging layer is prepared in an embodiment of the present disclosure.

### DETAILED DESCRIPTION OF THE EMBODIMENTS

When full-color light-emitting diode panels are manufactured in the related art, a Bank or a black matrix (BM) for photoetching needs to be additionally prepared to limit a graphic red conversion layer to emit red light, which has the problem of a complex manufacturing method.

In order to enable objectives, technical solutions and advantages of the embodiments of the present disclosure more clearly, the technical solutions of the embodiments of the present disclosure will be described clearly and completely in combination with accompanying drawings of the embodiments of the present disclosure below. Apparently, the described embodiments are only a part of the embodiments of the present disclosure, not all of the embodiments. Based on the described embodiments of the present disclosure, all other embodiments obtained by those of ordinary skill in the art without creative work shall fall within the protection scope of the present disclosure.

Unless otherwise defined, technical or scientific terms used herein shall have the ordinary meanings understood by those ordinarily skilled in the art to which the present disclosure pertains. The words “first”, “second” and the like used in the present disclosure do not represent any sequence, quantity or importance, but are only used to distinguish different constituent parts. The words “comprise” or “include” and the like indicate that an element or item appearing before such word covers listed elements or items appearing after the word and equivalents thereof, and does not exclude other elements or items. The words “connect” or “connecting” and the like are not limited to physical or mechanical connection, and may include electrical connection, no matter direct or indirect. The words “upper”, “lower”, “left”, “right” and the like are merely used to represent a relative position relationship, and after an absolute position of a described object changes, the relative position relationship may change accordingly.

In order to enable the following description of the present disclosure to be kept clear and concise, detained description of known functions and known components is omitted in the present disclosure.

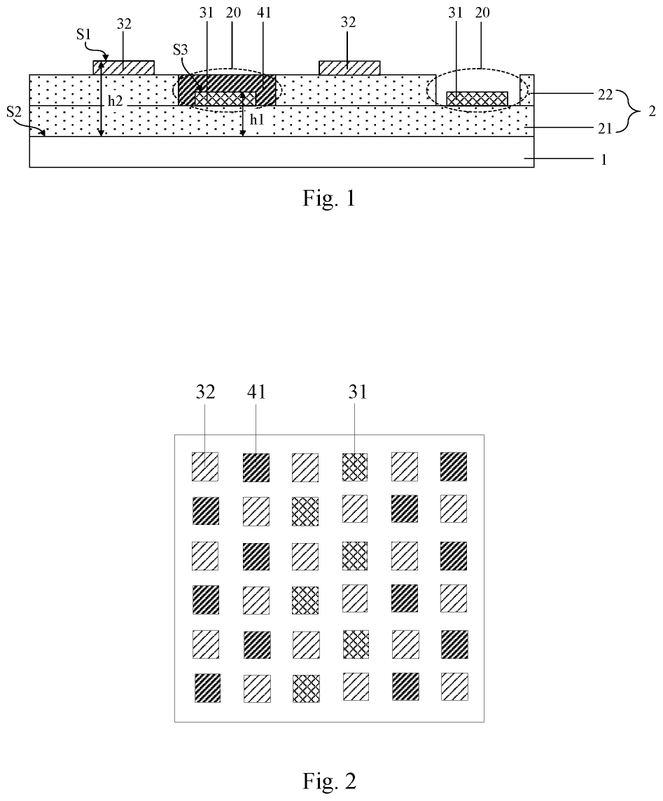

As shown in FIG. 1 and FIG. 2, an embodiment of the present disclosure provides a display substrate, including:
a base substrate 1;
a dielectric layer 2 located on one side of the base substrate 1, and the dielectric layer including a plurality of recessed portions 20;
a plurality of first-type light-emitting diodes 31, one of the first-type light-emitting diodes 31 being located in one of the recessed portions 20; wherein the first-type light-emitting diodes 31 may be blue light light-emitting diodes emitting blue light; and
a photoluminescence structure 41, the photoluminescence structure 41 being located in at least some of the recessed portions 20, being located on a side, facing away from the base substrate 1, of the first-type light-emitting diode 31. In some embodiments, the photoluminescence structure 41 may cover all regions in the recessed portions 20 except the first-type light-emitting diode 31; and the photoluminescence structure 41 may be the photoluminescence structure 41 emitting red light when irradiated by light emitted by the first-type light-emitting diode 31.

According to the display substrate provided by embodiments of the present disclosure, by arranging the plurality of recessed portions 20 in the dielectric layer 2, arranging the first-type light-emitting diode 31 in the recessed portions 20, and arranging the photoluminescence structure 41 in some of the recessed portions 20, and a retaining wall or a black matrix for limiting the photoluminescence structure 41 may not be individually manufactured, thereby simplifying processes, and alleviating the problem in the related art that when a full-color light-emitting diode panel is manufactured, a manufacturing method is complicated since a printing retaining wall or a black matrix for photoetching needs to be additionally prepared to limit a patterned red conversion layer.

During specific implementation, the display substrate may further include: a plurality of second-type light-emitting diodes 32 located on a side, away from the base substrate 1, of the dielectric layer 2, and a height from the second-type light-emitting diode 32 to the base substrate 1 is different from a height from the first-type light-emitting diode 31 to the base substrate 1. In some embodiments, in combination with FIG. 1, the height from the second-type light-emitting diode 32 to the base substrate 1 may be: a second distance h2 between a first surface S1 of a side, facing away from the base substrate 1, of the second-type light-emitting diode 32 and a second surface S2 of a side, facing the dielectric layer 2, of the base substrate 1; and the height from the first-type light-emitting diode 31 to the base substrate 1 may be: a first distance h1 between a third surface S3 of a side, facing away from the base substrate 1, of the first-type light-emitting diode 31 and the surface S2, that is, the first distance h1 is different from the second distance h2.

In embodiments of the present disclosure, the display substrate includes the plurality of second-type light-emitting diodes 32 located on the side, away from the base substrate 1, of the dielectric layer 2, that is, the second-type light-emitting diodes 32 are further arranged in a planar region of the dielectric layer 2, the height from the first-type light-emitting diode 31 to the base substrate 1 is different from the height from the second-type light-emitting diode 32 to the base substrate 1, then when the first-type light-emitting diodes 31 and the second-type light-emitting diodes 32 are manufactured, a step difference formed by the recessed portions 20 may be used to enable the first-type light-emitting diodes 31 to be formed into the recessed portions 20 more easily, and the difficulty of distinguishing corresponding transferring positions when different types of light-emitting diodes are transferred is reduced. Meanwhile, by means of the recessed portions 20 formed in the dielectric layer 2 for staggering the first-type light-emitting diodes 31 and the second-type light-emitting diode 32, the photoluminescence structure 41 is arranged in some of the recessed portions 20, and the retaining wall or the black matrix for limiting the photoluminescence structure 41 may not be individually manufactured, thereby simplifying the processes, and alleviating the problem in the related art that when the full-color light-emitting diode panel is manufactured, the manufacturing method is complicated since the printing retaining wall or the black matrix for photoetching needs to be additionally prepared to limit the patterned red conversion layer.

During specific implementation, the first-type light-emitting diodes 31 of the embodiment of the present disclosure may be micro light-emitting diodes (microled), and a size range is [1 μm, 10 μm] micron dimensions; and the second-type light-emitting diodes 32 may be micro light-emitting diodes (microled), and a size range is [1 μm, 10 μm] micron dimensions.

During specific implementation, in combination with FIG. 1, the dielectric layer 2 may include a first sub-dielectric layer 21 and a second sub-dielectric layer 22, and the second sub-dielectric layer 22 is located on a side, facing away from the base substrate 1, of the first sub-dielectric layer 21; and the recessed portions 20 are through holes penetrating through the second sub-dielectric layer 22, and the second-type light-emitting diode 32 is located on a side, facing away from the first sub-dielectric layer 21, of the second sub-dielectric layer 22 (that is, the second-type light-emitting diode 32 is located on a planar part of the second sub-dielectric layer 22), and is parallel to the first-type light-emitting diodes 31 in a direction parallel to the base substrate 1. In some embodiments, the dielectric layer 2 is a film subject to flattening after a drive structure is manufactured on the base substrate 1, that is, in the embodiment of the present disclosure, the existing dielectric layer 2 of the base substrate 1 may be used to form the recessed portions 20, then a film for limiting the first-type light-emitting diodes 31 may be prevented from being individually formed, and the existing dielectric layer 2 may further be used to limit the photoluminescence structure 41. Certainly, during specific implementation, the dielectric layer 2 may further be an integral film, and under the condition, the recessed portions 20 may be an integral structure not penetrating through the dielectric layer.

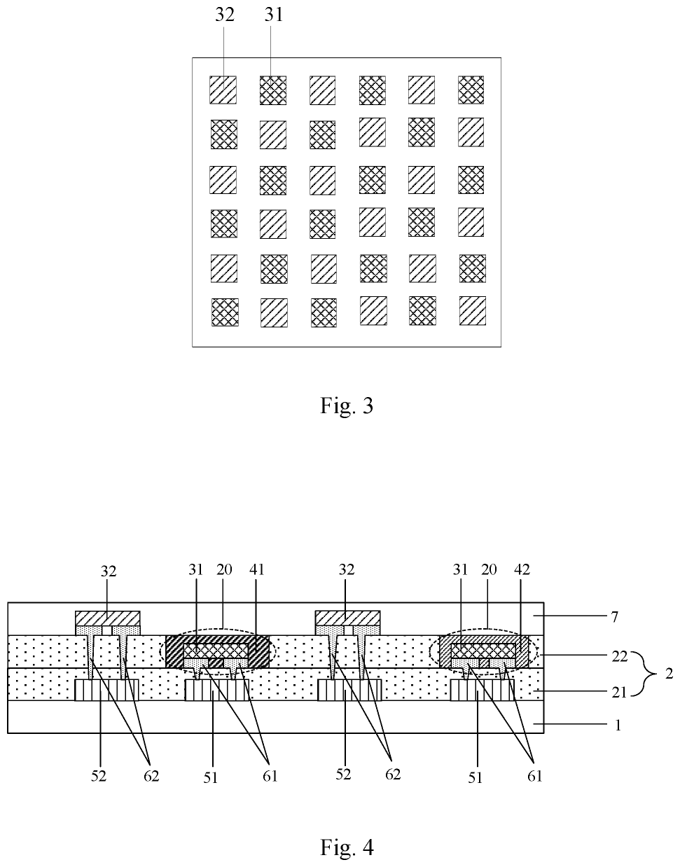

During specific implementation, in combination with FIG. 2 and FIG. 3, it should be noted that FIG. 3 does not show the photoluminescence structure 41 above the first-type light-emitting diodes 31 in order to illustrate a distribution relationship between the first-type light-emitting diodes 31 and the second-type light-emitting diodes 32 more clearly, a schematic diagram of the display substrate covered with the photoluminescence structure 41 may be shown in FIG. 2, and the first-type light-emitting diodes 31 and the second-type light-emitting diodes 32 are distributed in a plurality of rows and columns; in the same row, the first-type light-emitting diodes 31 and the second-type light-emitting diodes 32 are alternately distributed; and in the same column, the first-type light-emitting diodes 31 and the second-type light-emitting diodes 32 are alternately distributed. For the first-type light-emitting diodes 31 in the same row, first-type light-emitting diodes 31 spaced other one first-type light-emitting diode are provided with the photoluminescence structure 41. In some embodiments of the present disclosure, in the same row, the first-type light-emitting diodes 31 and the second-type light-emitting diodes 32 are alternately distributed, in the same column, the first-type light-emitting diodes 31 and the second-type light-emitting diodes 32 are alternately distributed, in a subsequent manufacturing process, the photoluminescence structure 41 may be formed above part of the first-type light-emitting diode 31, and then sequential distribution of the first-type light-emitting diodes 31, the second-type light-emitting diodes 32 and the photoluminescence structure 41 with different light-emitting colors is achieved, thereby achieving full-color display of the display substrate.

During specific implementation, referring to FIG. 4, the spaced first-type light-emitting diode 31 is further provided with a scattering structure 42 located in the recessed portion 20 on a side facing away from the base substrate 1. In some embodiments of the present disclosure, the spaced first-type light-emitting diode 31 is further provided with the scattering structure 42 on the side facing away from the base substrate 1, and light extraction at a position of the first-type light-emitting diode 31 where the photoluminescence structure 41 is not arranged may be more uniform. In some embodiments, a packaging layer 7 may further be arranged on a side, facing away from the second sub-dielectric layer 22, of the second-type light-emitting diode.

During specific implementation, light extraction colors of the first-type light-emitting diodes 31 in the recessed portions 20 are the same; light extraction colors of the second-type light-emitting diodes 32 are the same; and the photoluminescence structure 41 is made of a material emitting another color excited by the light extraction colors of the first-type light-emitting diodes 31. In some embodiments, the first-type light-emitting diodes 31 may be blue light light-emitting diodes, the second-type light-emitting diodes 32 may be green light light-emitting diodes, and the material of the photoluminescence structure 41 may be a quantum dot material excited by blue light to emit red light.

During specific implementation, in combination with FIG. 4, a drive structure is further arranged between the base substrate 1 and the first sub-dielectric layer 21, and the drive structure includes a first-type transistor 51 correspondingly electrically connected with the first-type light-emitting diodes 31, and a second-type transistor 52 correspondingly electrically connected with the second-type light-emitting diodes 32. In some embodiments, in the recessed portions 20, a first-type connecting pad 61 is further arranged between the first-type light-emitting diodes 31 and the first sub-dielectric layer 21; a second-type connecting pad 62 is further arranged between the second sub-dielectric layer 22 and the second-type light-emitting diodes 32; the first-type connecting pad 61 electrically connects the first-type light-emitting diodes 31 and the first-type transistor 51 by penetrating through a via hole of the first sub-dielectric layer 21; and the second-type connecting pad 62 electrically connects the second-type light-emitting diodes 32 and the second-type transistor 52 by penetrating through via holes of the first sub-dielectric layer 21 and the second sub-dielectric layer 22. In embodiments of the present disclosure, the display substrate further has the first-type transistor 51 for driving the first-type light-emitting diodes 31, and the second-type transistor 52 for driving the second-type light-emitting diodes 32, thereby achieving individual drive of the first-type light-emitting diodes 31 and individual drive of the second-type light-emitting diodes 32.

Based on the same inventive concept, an embodiment of the present disclosure further provides a display apparatus, including the display substrate provided by the embodiment of the present disclosure.

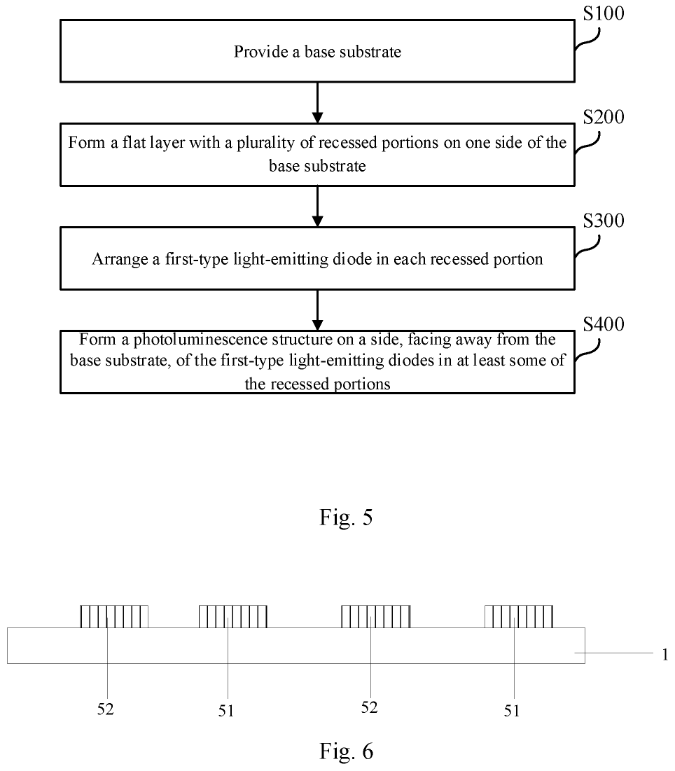

Based on the same inventive concept, an embodiment of the present disclosure further provides a manufacturing method of the display substrate provided by embodiments of the present disclosure, as shown in FIG. 5, including:
Step S100, a base substrate is provided;
Step S200, a dielectric layer with a plurality of recessed portions is formed on one side of the base substrate; in some embodiments, the step may include: a first sub-dielectric layer is formed on one side of the base substrate; a second sub-dielectric layer is formed on a side, facing away from the base substrate, of the first sub-dielectric layer; and through a patterning process, a through hole penetrating through the second sub-dielectric layer is formed in the second sub-dielectric layer to serve as a recessed portion;
Step S300, a first-type light-emitting diode is arranged in each recessed portion; in some embodiments, through a fluid self-assembly process, the first-type light-emitting diode may be arranged in each recessed portion; and
Step S400, a photoluminescence structure is formed on a side, facing away from the base substrate, of the first-type light-emitting diode in at least some of the recessed portions; and in some embodiments, through an ink-jet printing process or a spin coating process, the photoluminescence structure covering the first-type light-emitting diode may be formed in the least some of the recessed portions.

During specific implementation, after the step S400, the manufacturing method further includes: step S500, a plurality of second-type light-emitting diodes are arranged on the side, facing away from the base substrate, of the dielectric layer.

During specific implementation, the manufacturing method provided by embodiments of the present disclosure further includes: a scattering structure covering the first-type light-emitting diode is formed in the recessed portion not provided with the photoluminescence structure. In some embodiments, after the step S500, the scattering structure may be formed.

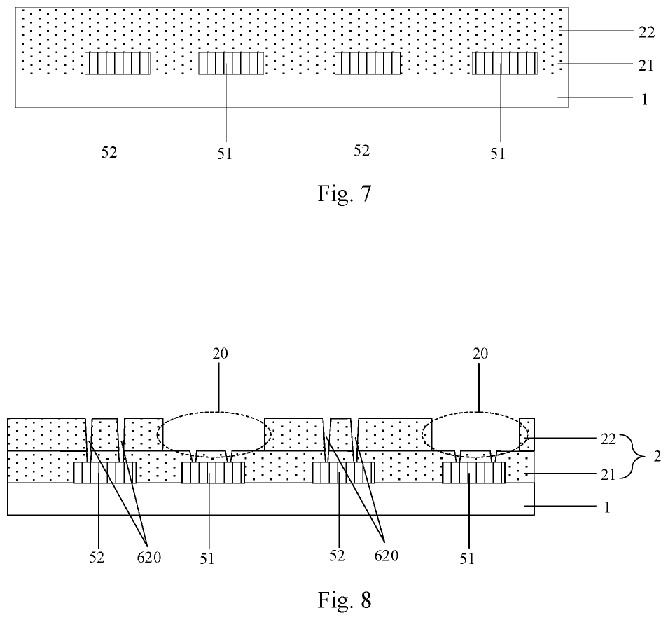

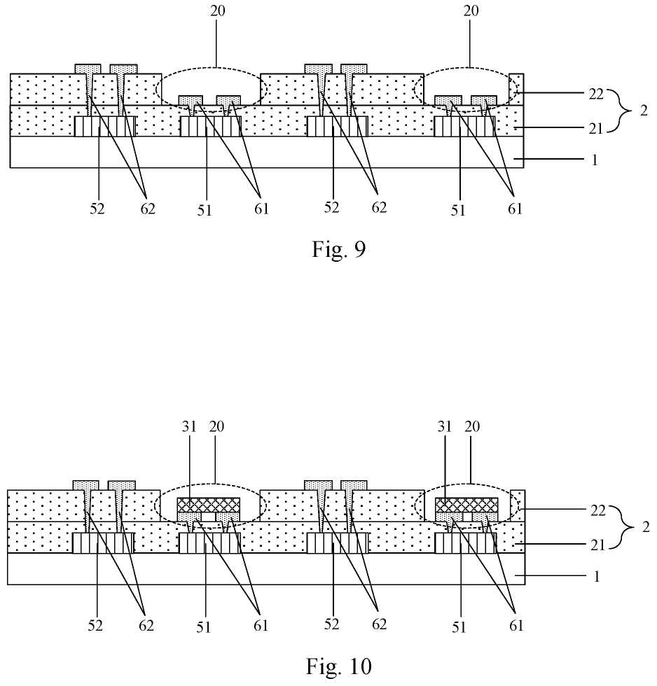

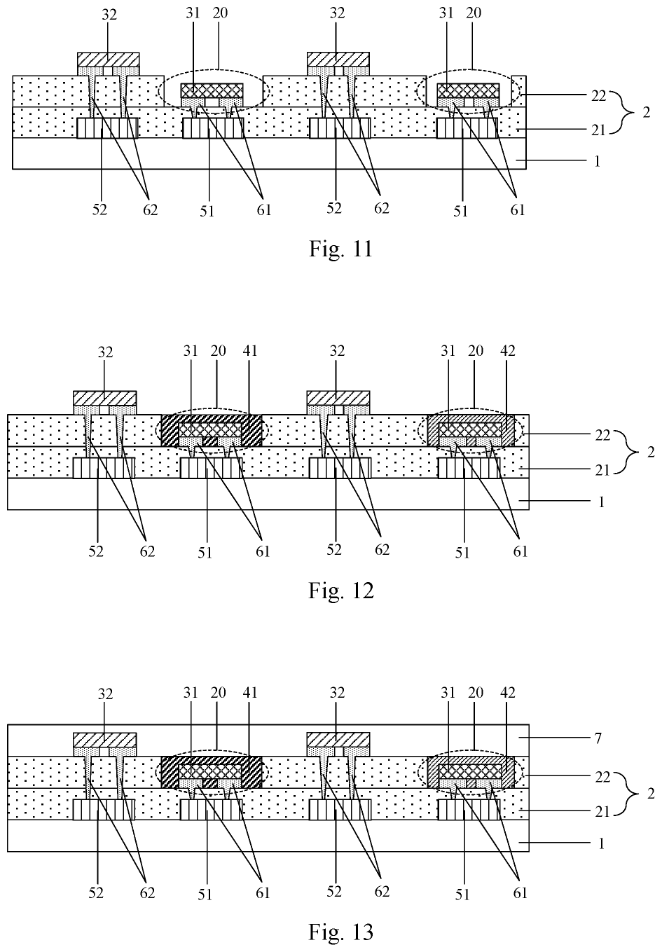

In combination with FIG. 6 to FIG. 13 below, the manufacturing method of the display substrate provided by embodiments of the present disclosure is further described in detail as follows:
Step 1: the drive structure (including the first-type transistor 51 and the second-type transistor 52) is manufactured on the base substrate 1 (such as a glass substrate), the type of the transistors is not limited, and the transistors may be oxide transistors or low-temperature polycrystalline silicon transistors, as shown in FIG. 6;
Step 2: after the drive structure is manufactured, the first sub-dielectric layer 21 (PLN1) is manufactured, a material of the first sub-dielectric layer 21 is resin, and a thickness may be 1 μm; and the second sub-dielectric layer 22 (PLN2) is manufactured on the first sub-dielectric layer 21, as shown in FIG. 7, a material of the second sub-dielectric layer 22 may further be resin, it is better to select the second sub-dielectric layer with lyophobicity, and a thickness L is [8 μm, 15 μm];
Step 3: a patterning process (half-tone process) is used for exposure, a via hole penetrating through the second sub-dielectric layer 22 and a connecting hole 620 enabling the subsequent first connecting pad 61 to be conducted with the first-type transistor 51 and enabling the subsequent second connecting pad 62 to be conducted with the second-type transistor 52 are formed by developing, the via hole is arranged as the recessed portion 20, a position of the via hole is as shown in FIG. 8, the via holes of the second sub-dielectric layer 22 are distributed at intervals, a length of the via holes of the second sub-dielectric layer 22 in a first direction (the first direction specifically may be a row direction of the first-type light-emitting diodes 31) is m, a width of the via holes of the second sub-dielectric layer 22 perpendicular to the first direction is n, where, m>m1, n>n1, m1 is the length of the first-type light-emitting diodes 31 in the first direction, n1 is the width of the first-type light-emitting diodes 31 perpendicular to the first direction, a range of a difference value of m−m1 is [2 μm, 5 μm], a range of a difference value of n−n1 is [2 μm, 5 μm] interval, that is, a [2 μm, 5 μm] interval is reserved at each edge; and the first connecting pad 61 and the second connecting pad 62 are formed, as shown in FIG. 9;
Step 4: firstly, mass transfer is performed on positions in the via holes in a fluid self-assembly mode, the recessed portion 20 is the first-type light-emitting diode 31 (blue light-emitting diode), in some embodiments, a brush bucket is used for rolling on the base substrate forming the first connecting pad 61 and the second connecting pad 62, a liquid suspension contains the blue light-emitting diode, then the blue light-emitting diode falls into the corresponding recessed portion 20 on the base substrate, and the yield is improved, as shown in FIG. 10; the height of the via hole of the second sub-dielectric layer 22 in the direction perpendicular to the base substrate 1 is L, the height L1 of the first-type light-emitting diodes 31 in the direction perpendicular to the base substrate 1 is [4 μm, 6 μm], the better L−L1>=6 μm; and certainly, other transfer print modes may further be adopted for transfer print of the first-type light-emitting diodes 31;
Step 5: mass transfer for the second-type light-emitting diodes 32 is performed on a position above the second sub-dielectric layer 22, and the mass transfer mode is not limited, as shown in FIG. 11;
Step 6: the red color quantum dot material (the photoluminescence structure 41) is manufactured above some of the first-type light-emitting diodes 31 in an ink-jet printing mode or a spin-coating mode, a scattering particle layer (the scattering structure 42) is manufactured above the first-type light-emitting diodes where the red color quantum dot material is not manufactured in the ink-jet printing mode or the spin-coating mode, and positions of the red color quantum dot material and the scattering particle layer are as shown in FIG. 12; and
Step 7: a chemical vapor deposition process is performed, that is, after the quantum dot material and scattering particles are formed, inorganic packaging needs to be performed, an inorganic packaging layer 7 may be SiNx or SiNOx, and a thickness is 6000 A or above, as shown in FIG. 13.

According to the display substrate, the display apparatus and the manufacturing method of the display substrate provided by embodiments of the present disclosure, the plurality of recessed portions are arranged on the dielectric layer of the display substrate, the first-type light-emitting diodes are arranged in the recessed portions, the height from the first-type light-emitting diodes to the base substrate is different from the height from the second-type light-emitting diodes to the base substrate, then when the first-type light-emitting diodes and the second-type light-emitting diodes are manufactured, the step difference formed by the recessed portions may be used to enable the first-type light-emitting diodes to be formed into the recessed portions more easily, and the difficulty of distinguishing the transfer print position when different types of the light-emitting diodes are transferred is reduced. Meanwhile, by means of the recessed portions of the dielectric layer for staggering the first-type light-emitting diodes and the second-type light-emitting diode, the photoluminescence structure is arranged in some of the recessed portions, and the retaining wall or the black matrix for limiting the photoluminescence structure may not be individually manufactured, thereby simplifying the processes, and alleviating the problem in the related art that when the full-color light-emitting diode panel is manufactured, the manufacturing method is complicated since the printing retaining wall or the black matrix for photoetching needs to be additionally prepared to limit the patterned red conversion layer.

It will be apparent to those skilled in the art that various modifications and variations may be made to the present disclosure without departing from the spirit or scope of the present disclosure. In this way, if these modifications and variations of the present disclosure fall within the scope of the claims of the present disclosure and their equivalent art, the present disclosure also intends to include these modifications and variations.

1. A display substrate, comprising:
a base substrate;
a dielectric layer located on one side of the base substrate, and comprising a plurality of recessed portions;
a plurality of first-type light-emitting diodes, each of the first-type light-emitting diodes being located in one of the recessed portions respectively; and
a photoluminescence structure, the photoluminescence structure being located in at least some of the recessed portions, and located on a side, facing away from the base substrate, of the first-type light-emitting diode, and the photoluminescence structure configured to convert light of a first wave length emitted by the first-type light-emitting diode into light of a second wave length.

2. The display substrate according to claim 1, further comprising: a plurality of second-type light-emitting diodes located on a side, facing away from the base substrate, of the dielectric layer, and a height from the second-type light-emitting diode to the base substrate being different from a height from the first-type light-emitting diode to the base substrate.

3. The display substrate according to claim 2, wherein the dielectric layer comprises a first sub-dielectric layer and a second sub-dielectric layer, and the second sub-dielectric layer is located on a side, facing away from the base substrate, of the first sub-dielectric layer; and
the recessed portions are through holes penetrating through the second sub-dielectric layer, and the second-type light-emitting diodes are located on a side, facing away from the first sub-dielectric layer, of the second sub-dielectric layer, and are parallel to the first-type light-emitting diodes in a direction parallel to the base substrate.

4. The display substrate according to claim 3, wherein the first-type light-emitting diodes and the second-type light-emitting diodes are distributed in a plurality of rows and columns; and
in a same row, the first-type light-emitting diodes and the second-type light-emitting diodes are alternately distributed; and in a same column, the first-type light-emitting diodes and the second-type light-emitting diodes are alternately distributed.

5. The display substrate according to claim 4, wherein for the first-type light-emitting diodes in the same row, first-type light-emitting diodes spaced other one first-type light-emitting diode are provided with the photoluminescence structure.

6. The display substrate according to claim 5, wherein first-type light-emitting diodes not provided with the photoluminescence structure are further provided with a scattering structure located in the recessed portion on a side facing away from the base substrate.

7. The display substrate according to claim 2, wherein light extraction colors of the first-type light-emitting diodes in the recessed portions are the same; and light extraction colors of the second-type light-emitting diodes are the same.

8. The display substrate according to claim 7, wherein the first-type light-emitting diodes are blue light light-emitting diodes, the second-type light-emitting diodes are green light light-emitting diodes, and a material of the photoluminescence structure is a quantum dot material excited by blue light to emit red light.

9. The display substrate according to claim 3, further comprising: a drive structure located between the base substrate and the first sub-dielectric layer, wherein the drive structure comprises a first-type transistor correspondingly and electrically connected with the first-type light-emitting diodes, and a second-type transistor correspondingly and electrically connected with the second-type light-emitting diodes.

10. The display substrate according to claim 9, wherein in the recessed portions, a first-type connecting pad is further arranged between the first-type light-emitting diodes and the first sub-dielectric layer;
a second-type connecting pad is further arranged between the second sub-dielectric layer and the second-type light-emitting diodes;
the first-type connecting pad electrically connects the first-type light-emitting diodes and the first-type transistor by a via hole penetrating through the first sub-dielectric layer; and
the second-type connecting pad electrically connects the second-type light-emitting diodes and the second-type transistor by a via hole penetrating through the first sub-dielectric layer and the second sub-dielectric layer.

11. A display apparatus, comprising a display substrate comprising:
a base substrate;
a dielectric layer located on one side of the base substrate, and comprising a plurality of recessed portions;
a plurality of first-type light-emitting diodes, each of the first-type light-emitting diodes being located in one of the recessed portions respectively; and
a photoluminescence structure, the photoluminescence structure being located in at least some of the recessed portions, and located on a side, facing away from the base substrate, of the first-type light-emitting diode, and the photoluminescence structure configured to convert light of a first wave length emitted by the first-type light-emitting diode into light of a second wave length.

12. A manufacturing method of the display substrate according to claim 1, comprising:
providing a base substrate;
forming a dielectric layer with a plurality of recessed portions on one side of the base substrate;
arranging a first-type light-emitting diode in each recessed portion; and
forming a photoluminescence structure on a side, facing away from the base substrate, of the first-type light-emitting diodes in at least some of the recessed portions.

13. The manufacturing method according to claim 12, wherein the forming the dielectric layer with the plurality of recessed portions on one side of the base substrate, comprises:
forming a first sub-dielectric layer on one side of the base substrate;
forming a second sub-dielectric layer on a side, facing away from the base substrate, of the first sub-dielectric layer; and
forming a through hole penetrating through the second sub-dielectric layer on the second sub-dielectric layer to serve as the recessed portion through a patterning process.

14. The manufacturing method according to claim 13, wherein the arranging the first-type light-emitting diode in each recessed portion, comprises:
arranging the first-type light-emitting diode in each recessed portion through a fluid self-assembly process.

15. The manufacturing method according to claim 14, wherein the forming the photoluminescence structure on the side, facing away from the base substrate, of the first-type light-emitting diodes in at least some of the recessed portions, comprises:
forming the photoluminescence structure covering the first-type light-emitting diode in at least some of the recessed portions through an ink-jet printing process or a spin-coating process.

16. The manufacturing method according to claim 12, wherein after the forming the photoluminescence structure on the side, facing away from the base substrate, of the first-type light-emitting diodes in at least some of the recessed portions, the manufacturing method further comprises:
arranging a plurality of second-type light-emitting diodes on a side, facing away from the base substrate, of the dielectric layer.

17. The manufacturing method according to claim 12, further comprising:
forming a scattering structure coating the first-type light-emitting diodes in the recessed portion not provided with the photoluminescence structure.

18. The display apparatus according to claim 11, wherein the display substrate further comprises: a plurality of second-type light-emitting diodes located on a side, facing away from the base substrate, of the dielectric layer, and a height from the second-type light-emitting diode to the base substrate being different from a height from the first-type light-emitting diode to the base substrate.

19. The display apparatus according to claim 18, wherein the dielectric layer comprises a first sub-dielectric layer and a second sub-dielectric layer, and the second sub-dielectric layer is located on a side, facing away from the base substrate, of the first sub-dielectric layer; and
the recessed portions are through holes penetrating through the second sub-dielectric layer, and the second-type light-emitting diodes are located on a side, facing away from the first sub-dielectric layer, of the second sub-dielectric layer, and are parallel to the first-type light-emitting diodes in a direction parallel to the base substrate.

20. The display apparatus according to claim 19, wherein the first-type light-emitting diodes and the second-type light-emitting diodes are distributed in a plurality of rows and columns; and
in a same row, the first-type light-emitting diodes and the second-type light-emitting diodes are alternately distributed; and in a same column, the first-type light-emitting diodes and the second-type light-emitting diodes are alternately distributed.
